(19) United States
(12) Patent Application Publication
(10) Pub. No.: US 2012/0006591 A1
(43) Pub. Date: Jan. 12, 2012

(54) Wiring Substrate and Method for Manufacturing Wiring Substrate

(76) Inventors: Kentaro Kaneko, Nagano-shi (JP); Kotaro Kodani, Nagano-shi (JP); Kazuhiro Kobayashi, Nagano-shi (JP); Junichi Nakamura, Nagano-shi (JP)

(21) Appl. No.: 13/176,876

(22) Filed: Jul. 6, 2011

(30) Foreign Application Priority Data
Jul. 8, 2010 (JP) 2010-155785

(51) Int. Cl. H05K 1/11; H05K 3/40

(52) U.S. Cl. 174/262; 174/261; 29/829

(57) ABSTRACT

A wiring substrate that prevents the occurrence of delamination near an interface between an insulation layer and an electrode pad, which is formed in a recess of the insulation layer. An adjustment layer is formed in an opening in a resist, which is applied to a support body, to adjust the shape of the electrode pad. The adjustment layer includes a flat surface, which is substantially parallel to the support body, and an inclined surface, which extends from a rim of the flat surface toward the support body and to the side wall of the opening. A pad body of the electrode pad and an insulation layer including a wire is formed on the adjustment layer. The support body and adjustment layer are etched to expose the pad body.

### CROSS-REFERENCE TO RELATED APPLICATIONS

This application is based upon and claims the benefit of priority from prior Japanese Patent Application No. 2010-155785, filed on Jul. 8, 2010, the entire contents of which are incorporated herein by reference.

### BACKGROUND OF THE INVENTION

The present invention relates to a wiring substrate and a method for manufacturing a wiring substrate.

A wiring substrate includes a surface to which an insulation layer is applied. The insulation layer includes an opening. An electrode pad is formed in the opening. For example, Japanese Laid-Open Patent Publication No. 2007-13092 describes a wiring substrate including an electrode pad formed in an opening, which has a tetragonal cross-section and extends from the surface of an insulation layer. The opening has a depth, and the electrode pad has a thickness that is less than the depth of the opening. In the wiring substrate, the surface of the insulation layer is located outward from the surface of the electrode pad. Thus, when a coupling terminal of an LSI is soldered and coupled to the electrode pad, solder is prevented from flowing to an adjacent electrode. This suppresses short-circuiting.

The wiring substrate is manufactured as described below. First, solder resist is applied to a support body. The solder resist includes an opening used to form an electrode pad. Then, an adjustment layer is formed in the opening to adjust the height of the electrode pad. The adjustment layer has a tetragonal cross-section and a thickness. The thickness of the adjustment layer is less than a depth of opening in the solder resist. An insulation layer, which covers the electrode pad, is formed on the support body. A via is formed in the insulation layer at a location corresponding to the electrode pad. A pattern wire is formed on the insulation layer in correspondence with the via. Then, solder resist, which covers the pattern wire, is formed on surface of the insulation layer. Further, an opening is formed in the solder resist to expose part of the pattern wire. Wet etching is performed to remove the support body and the adjustment layer. This exposes the surface of the electrode pad and obtains a wiring substrate in which the surface of the insulation layer (solder resist) is located outward from the surface of the electrode pad.

In the electrode pad of Japanese Laid-Open Patent Publication No. 2007-13092, wet etching is performed to remove a support body 60 and an adjustment layer 61, which are shown in FIG. 7(a). This may etch a peripheral part of the electrode pad 62, that is, the interface leading to an insulation layer 63, as shown in FIG. 7(b). In such a case, a groove forms between the peripheral part of the electrode pad 62 and the insulation layer 63. As a result, the electrode pad 62 and the insulation layer 63 are apt to delaminate or crack from the groove.

### SUMMARY OF THE INVENTION

One aspect of the present invention is a method for manufacturing a wiring substrate including an electrode pad. The method includes forming a resist on a support body. The resist includes an opening at a location corresponding to where the electrode pad of the wiring substrate is formed. The method further includes forming an adjustment layer on the support in the opening of the resist. The adjustment layer includes a first flat surface, which is substantially parallel to the support body, and a first inclined surface, which extends from a rim of the first flat surface toward a side wall of the opening. The method also includes forming the electrode pad on the adjustment layer. The electrode pad includes a peripheral part, which includes a second inclined surface corresponding to the first inclined surface of the adjustment layer, and a central part, which includes a second flat surface corresponding to the first flat surface of the adjustment layer, and the central part is recessed from the peripheral part. Further, the method includes forming an insulation layer on the support body and forming a wiring layer on the insulation layer. The wiring layer is electrically coupled to the electrode pad. Additionally, the method includes removing the support body and the adjustment layer.

A further aspect of the present invention is a wiring substrate including an insulation layer and an electrode pad exposed from the insulation layer. The electrode pad includes a central part, which includes a flat surface, and a peripheral part, and the central part is recessed from the peripheral part. A wiring layer is arranged on the insulation layer and electrically coupled to the electrode pad.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a cross-sectional view showing a wiring substrate according to one embodiment of the present invention;

FIG. 2 is an enlarged cross-sectional view showing an electrode pad and its surrounding in the wiring substrate of FIG. 1;

FIGS. 3(a) to 3(c) and 3(e) are cross-sectional views showing the procedures for manufacturing the wiring substrate of FIG. 1, and FIGS. 3(d) and 3(f) are enlarged views of FIGS. 3(c) and 3(e), respectively;

FIGS. 4(a) to 4(f) are cross-sectional views showing the procedures for manufacturing the wiring substrate of FIG. 1;

FIGS. 5(a) to 5(c) are cross-sectional views showing surface plating layers in other embodiments of the present invention;

FIGS. 6(a) to 6(c) are cross-sectional views showing the procedures for manufacturing a wiring substrate including a surface plating layer formed on an adjustment layer in other embodiments of the present invention; and

FIGS. 7(a) and 7(b) are cross-sectional views showing a wiring substrate of the prior art.

### DETAILED DESCRIPTION OF THE INVENTION

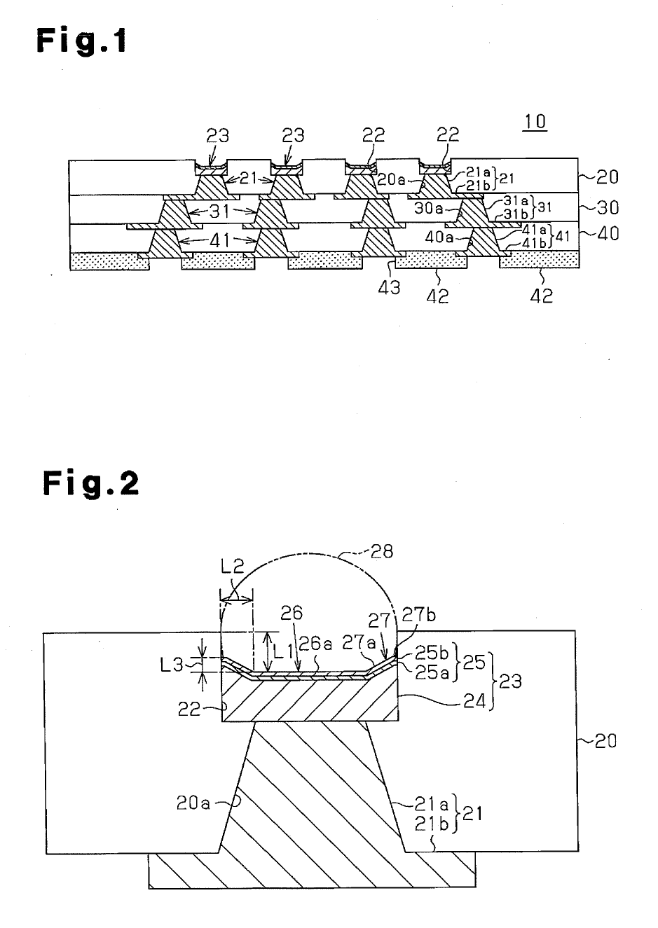

One embodiment of the present invention will now be described with reference to FIGS. 1 to 4.

FIG. 1 shows a wiring substrate 10 including laminated first, second, and third insulation layers 20, 30, and 40. Wires 21, 31, and 41 are formed in the insulation layers 20, 30, and 40, respectively. The insulation layers 20, 30, and 40 are formed from, for example, epoxy resin, and the wires 21, 31, and 41 are formed from a metal, such as copper.

Via holes 20a are formed in the first insulation layer 20. Each first wire 21 forms a via 21a, which is formed in each via hole 20a, and a wiring pattern 21b, which is coupled to the via 21a. In the same manner as the first wire 21, each second wire 31 forms a via 31a, which is formed in each via hole 30a of the second insulation layer 30, and a wiring pattern 31b, which is coupled to the via 31a. Further, each third wire 41 forms a via 41a, which is formed in each via hole 40a of the third insulation layer 40, and a wiring pattern 41b, which is coupled to the via 41a.

The first insulation layer 20 includes recesses 22, which correspond to the first wires 21. Each recess 22 is circular and has a diameter of, for example, 50 to 500 μm. The cross-sectional views of FIGS. 1 to 4 are taken along a plane extending through the centers of the recesses 22.

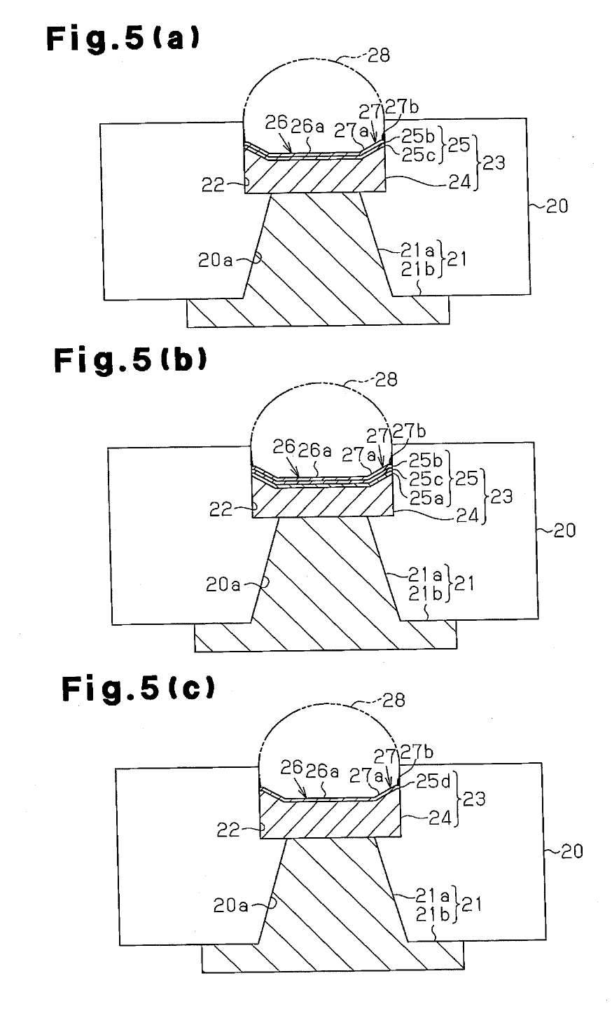

As shown in FIG. 2, an electrode pad 23 is formed in each recess 22 of the first insulation layer 20. The electrode pad 23 includes a pad body 24 and a surface plating layer 25, which is formed on the surface of the pad body 24. The pad body 24 is formed from copper. The surface plating layer 25 includes a nickel layer 25a, which is formed directly on the pad body 24, and a gold layer 25b, which is formed on the nickel layer 25a. The pad body 24 has a thickness of, for example, 5 to 25 μm. The nickel layer 25a has a thickness of, for example, 0.005 to 0.5 μm. The surface plating layer 25 is not limited to the two structures of the nickel layer 25a and the gold layer 25b. For example, the surface plating layer 25 may have a double layer structure including a palladium layer 25c and a gold layer 25b as shown in FIG. 5(a), a triple-layer structure including a nickel layer 25a, a palladium layer 25c, and a gold layer 25b as shown in FIG. 5(b), or a single-layer structure including a tin layer 25d as shown in FIG. 5(c).

The electrode pad 23 includes a flat portion 26, which is located at the central part of the electrode pad 23, and a projected portion 27, which projects from the rim of the flat portion 26. The flat portion 26 includes a flat surface 26a, which is substantially parallel to a bottom surface of the recess 22 in the first insulation layer 20. The projected portion 27 includes an inclined surface 27a, which is inclined toward the edge of the recess 22 and extends from the rim of the flat surface 26a to the side wall of the recess 22. The distance L1 from the top of the recess 22 to the flat surface 26a is, for example, 10 to 15 μm. The distance L2 from the side wall of the recess 22 to the rim of the flat portion 26 is, for example, 10 to 15 μm. The projected portion 27 has a height L3 of, for example, less than 5 μm.

The electrode pad 23, which includes the flat portion 26 and the projected portion 27, is in contact with the side wall of the recess 22 in the first insulation layer 20. Thus, in comparison to an electrode pad that includes only a flat portion, the projected portion 27 increases the area of contact with the first insulation layer 20. This improves the adhesion between the electrode pad 23 and the first insulation layer 20 and suppresses cracking and like at the interface between the electrode pad 23 and the first insulation layer 20.

FIG. 2 shows a solder ball 28 coupled to the electrode pad 23. The electrode pad 23 is coupled by the solder ball 28 to a semiconductor element pad (not shown).

As described above, the peripheral part of the electrode pad 23 defines the projected portion 27. Thus, the solder ball 28 is easily received by the central part (flat portion 26), which is recessed from the peripheral part (projected portion 27). Further, the solder ball 28 is supported by the flat portion 26 and projected portion 27 of the electrode pad 23. Thus, in comparison to an electrode pad that includes only a flat portion, the area of contact between the solder ball 28 and the electrode pad 23 increases. Further, gaps are decreased between the solder ball 28, the electrode pad 23, and the walls of the recess 22. Accordingly, the electrode pad 23 of the present embodiment supports the solder ball 28 over a larger area (contact point) when stress acts on the solder ball 28. This stably supports the solder ball 28.

In the present embodiment, the surface of the electrode pad 23 is neither evenly round nor flat and includes the flat surface 26a and the inclined surface 27a. Further, a corner is formed in the interface between the flat surface 26a and the inclined surface 27a. When an electrode pad includes an evenly round or flat surface, stress may be applied to a solder ball along the surface of the electrode pad, and cracks may form along the surface. This may propagate the stress or cracks along the surface of the electrode pad. However, in the present embodiment, the surface of the electrode pad 23 is not an even surface. Thus, for example, when stress is applied to the solder ball 28 along the inclined surface 27a, the propagation of the stress is stopped near the interface between the flat surface 26a and the inclined surface 27a.

As shown in FIG. 1, a solder resist 42 is formed on the third insulation layer 40. The solder resist 42 includes openings 43 corresponding to the third wires 41. This partially exposes the wiring pattern 41b of the third wires 41. The third wires 41 are electrically coupled to electrodes of a printed substrate. This electrically couples a semiconductor element and printed substrate with the wiring substrate 10.

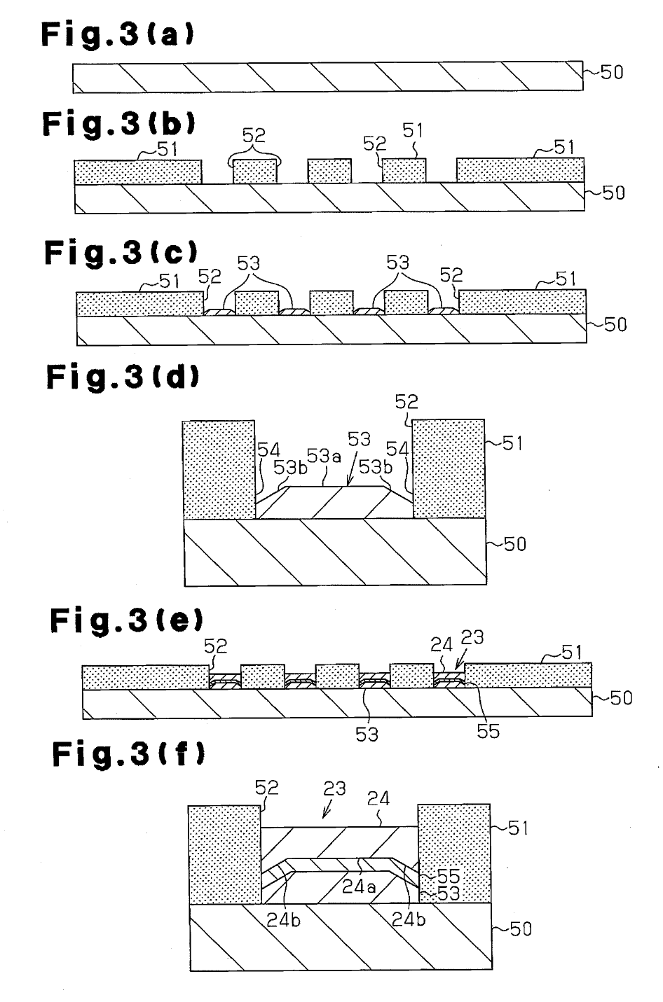

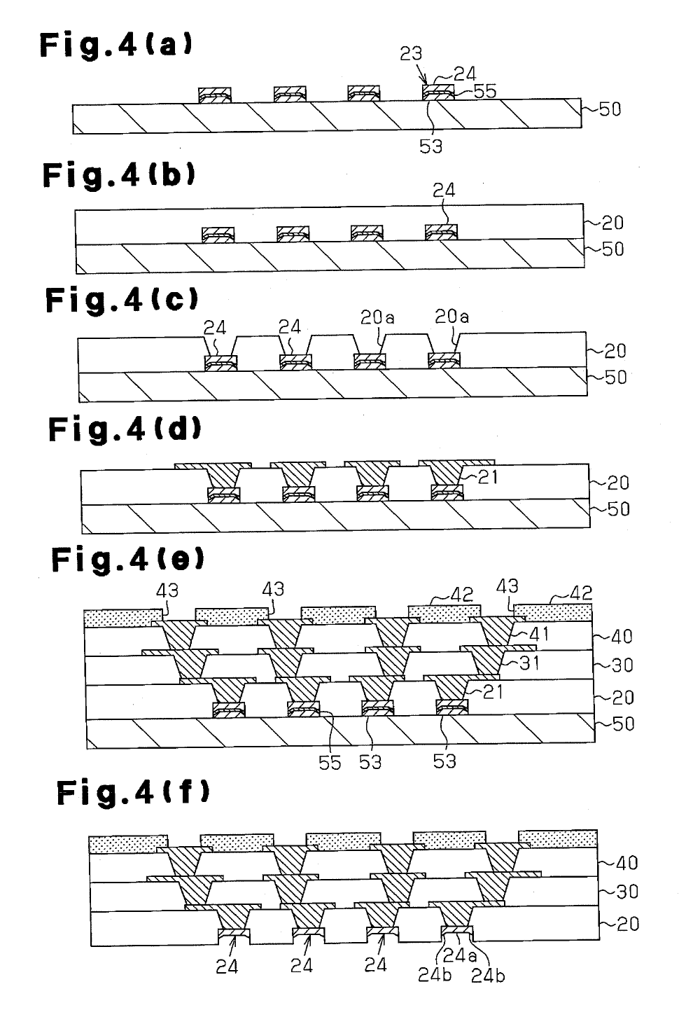

A method for manufacturing the wiring substrate 10 will now be described with reference to FIGS. 3 and 4.

To manufacture the wiring substrate 10, referring to FIG. 3(a), a support body 50 is first prepared. A metal plate or metal foil may be used as the support body 50. In the present embodiment, a copper foil is used. Then, referring to FIG. 3(b), a resist 51 is formed on the support body 50. For example, a dry film may be used as the resist 51. The resist 51 includes openings 52 formed at locations corresponding to where the electrode pads 23 are formed.

Referring to FIG. 3(c), adjustment layers 53, which adjust the shapes of the electrode pads 23, are formed in the openings 52 of the resist 51. The adjustment layers 53 are formed by performing electrolytic plating that applies copper plating to portions of the support body 50 exposed through the openings 52 of the resist 51. Thus, the adjustment layers 53 are formed from copper. The electrolytic plating uses inorganic components, such as copper sulfate, sulfuric acid, and chlorine, as a plating liquid and uses organic components, such as a leveler, polymer, and brightener, as an additive. Each adjustment layer 53 has a thickness of, for example, 10 to 15 μm, in correspondence with the distance L1 from the top of the recess 22 (first insulation layer 20) to the flat surface 26a (electrode pad 23) as shown in FIG. 2. The thickness of each adjustment layer 53 is less than the depth of each opening 52.

A flat plating layer is obtained at a central part of each opening 52 by adjusting the composition of the plating liquid. Accordingly, in the present embodiment, as shown in FIG. 3, each adjustment layer 53 is formed to include a flat surface 53a (first flat surface), which is substantially parallel to the bottom surface of the corresponding opening 52, and an inclined surface 53b (first inclined surface), which extends from the rim of the flat surface 53a toward the support body 50 and to the wall of the opening 52. In the example shown in FIG. 3(d), the adjustment layer 53 is hexagonal in cross-section. However, when electrolytic plating is performed during a short period, the inclined surface 53b is near the support body 50. Thus, the adjustment layer 53 may be trapezoidal in cross-section. In this manner, a groove 54 having a generally V-shaped cross-section is formed between the inclined surface 53b of the adjustment layer 53 and the wall of the opening 52.

Referring to FIG. 3(e), the pad body 24 of the electrode pad 23 is formed on the surface of each adjustment layer 53. In the present embodiment, referring to FIG. 3(f), a nickel layer 55 having a thickness of 0.05 to 10 μm is formed on the surface of each adjustment layer 53. Then, a copper plating is applied to form the pad body 24 with a thickness of 5 to 25 μm. As shown in FIG. 3(f), the nickel layer 55 is formed and shaped along the surface of the adjustment layer 53, and the pad body 24 is thus formed to include a flat surface 24a (second flat surface) and an inclined surface 24b (second inclined surface).

Then, referring to FIG. 4(a), the resist 51 is removed. Further, the pad bodies 24 and the support body 50 undergo surface roughening, which obtains a surface roughness of 0.5 to 2 μm. Surface roughening is performed so that the first insulation layer 20 easily adheres to the support body 50 and the pad bodies 24 in the next process shown in FIG. 4(b). Anisotropic etching (e.g., wet etching) may be performed as the roughening process.

In the process shown in FIG. 4(b), a buildup process is performed to form the first insulation layer 20 on the surface of the support body 50 and cover the pad bodies 24. More specifically, a resin film is laminated on the support body 50. A heating treatment is performed while pressing the resin film. Then, the resin film is solidified to form the first insulation layer 20. Referring to FIG. 4(c), portions of the first insulation layer 20 corresponding to the pad bodies 24 are, for example, irradiated with a laser beam to form the via holes 20a and expose the pad bodies 24. Then, referring to FIG. 4(d), a first wire 21 is formed in each via hole 20a by performing, for example, a semi-additive process.

Referring to FIG. 4(e), the second insulation layer 30 and the second wires 31 are formed in the same manner. Then, the third insulation layer 40 and the third wires 41 are formed in the same manner. This obtains a wiring member. The surface of the third insulation layer 40 is covered with the solder resist 42, and the openings 43 are formed in correspondence with the third wires 41. A method for forming a wiring member including the first to third insulation layers 20, 30, and 40 and the wires 21, 31, and 41 may employ various types of wire formation processes such as a sub-tractive process in addition to the semi-additive process.

Referring to FIG. 4(f), for example, wet etching is performed to remove the support body 50 and the adjustment layers 53. Then, the nickel layers 55 are etched to expose the pad bodies 24. When a pad body includes only a flat surface, the side wall of each recess 22 in the first insulation layer 20 contacts the surface of the corresponding pad body at a generally right angle. In the present embodiment, the peripheral part of the pad body 24 is defined by the inclined surface 24b. Thus, the side wall of each recess 22 in the first insulation layer 20 contacts the surface of the corresponding pad body 24 at an obtuse angle. As a result, etching liquid does not remain near the peripheral part of each pad body 24. Further, even when the pad body 24 is etched, the distal end of the inclined surface 24b would just be rounded. In this manner, etching is suppressed at the interface between the pad body 24 and the first insulation layer 20.

Finally, in a state in which the pad body 24 is exposed, referring to FIG. 2, electroless plating is performed to carry out surface treatment on the pad bodies 24 and sequentially form the nickel layer 25a and the gold layer 25b. The surface treatment is not limited to the formation of the surface plating layer 25, which includes the nickel layer 25a and the gold layer 25b. For example, electroless plating may be performed to form a surface plating layer including the three layers of nickel, palladium, and gold on the surface of the pad body 24 (FIG. 5(b)). Electroless plating may also be performed to form a surface plating layer including the two layers of palladium and gold on the surface of the pad body 24 (FIG. 5(a)). Further, electroless plating may also be performed to form a surface plating layer including only tin on the surface of the pad body 24 (FIG. 5(c)). An organic solderbility preservative (OSB) process may also be performed to apply an anti-oxidation film, which is formed from an organic component, on the surface of the pad body 24. This forms the electrode pads 23. The wiring substrate 10 is manufactured in this manner.

The advantages of the present embodiment will now be described.

(1) When manufacturing the wiring substrate 10, the adjustment layer 53 includes the flat surface 53a, which is substantially parallel to the support body 50, and the inclined surface 53b, which extends from the rim of the flat surface 53a toward the surface of the support body 50 and to the wall of the corresponding opening 52 in the resist 51. As a result, the pad body 24, which is formed on the adjustment layer 53, includes the flat surface 24a, which is arranged at the central part in correspondence with the surface of the adjustment layer 53, and the inclined surface 24b, which is arranged at the peripheral part and projects outward from the central part. Accordingly, when etching the support body 50 and the adjustment layer 53, even if part of the pad body 24 were to be etched, the distal end of the projecting peripheral part including the inclined surface 24b would just be rounded. This suppresses etching at the interface between the pad body 24 and the first insulation layer 20. Further, since the interface between the electrode pad 23 and the first insulation layer 20 is not etched, the occurrence of delamination at the interface is suppressed.

(2) In the wiring substrate 10, the electrode pad 23 is arranged in each recess 22, which is formed in the surface of the first insulation layer 20. The electrode pad 23 includes the flat portion 26, which includes the flat surface 26a, and the projected portion 27, which includes the inclined surface 27a. Since the electrode pad 23, which includes the flat portion 26 and the projected portion 27, contacts the first insulation layer 20, the projected portion 27 increases the area of contact with the first insulation layer 20 in comparison with an electrode pad that includes only the flat portion. This improves the adhesion between the electrode pad 23 and the first insulation layer 20 and suppresses cracking at the interface between the electrode pad 23 and the first insulation layer 20.

(3) The electrode pad 23, which includes the flat portion 26 and the projected portion 27, is coupled to the solder ball 28. Thus, the solder ball 28 is easily received in the central part of the electrode pad 23, and the area of contact is increased between the solder ball 28 and the electrode pad 23 in comparison to when the electrode pad includes only the flat portion. This improves the stability of the solder ball 28, and the electrode pad 23 supports the solder ball 28 with further stability.

It should be apparent to those skilled in the art that the present invention may be embodied in many other specific forms without departing from the spirit or scope of the invention. Particularly, it should be understood that the present invention may be embodied in the following forms.

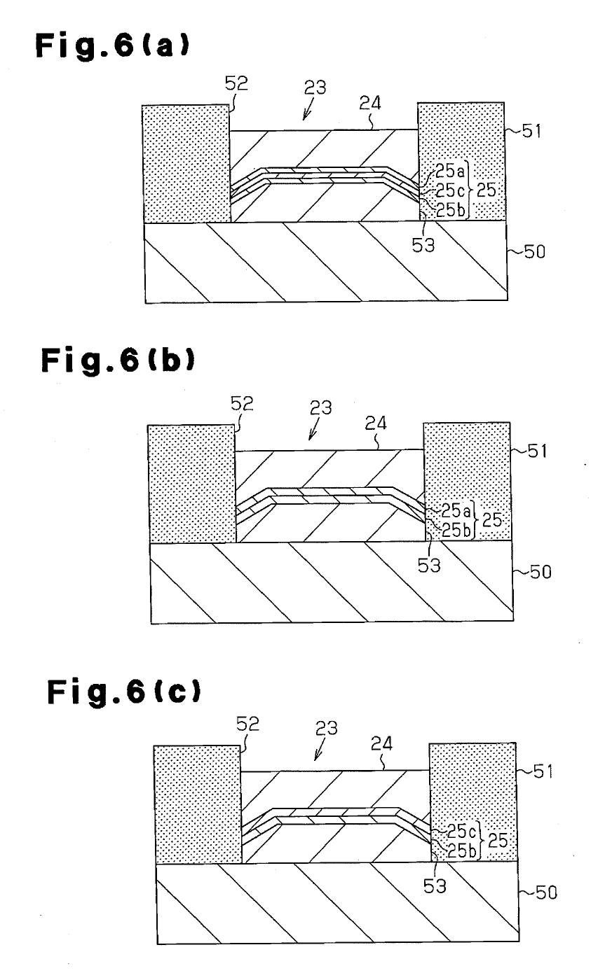

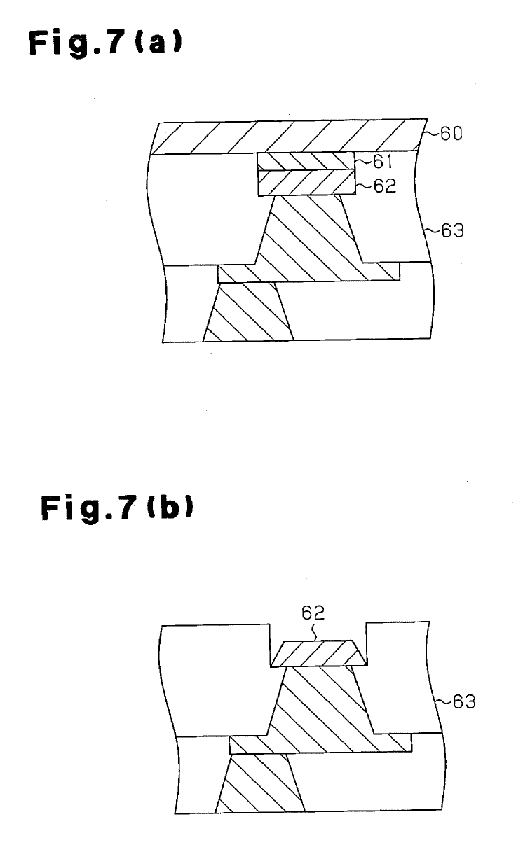

In the above embodiment, in the process shown in FIG. 3(e), the pad body 24 is formed after applying the nickel layer 55 to the surface of the adjustment layer 53. Further, in the support body removal process shown in FIG. 4, after removal of the support body 50, the adjustment layer 53, and the nickel layer 55, the surface plating layer 25 is formed on the pad body 24. In a further embodiment, in the process for forming the electrode pad 23 shown in FIG. 3(e), the pad body 24 is formed after applying the surface plating layer 25 to the adjustment layer 53 at a location corresponding to the nickel layer 55. Further, in the support body removal process of FIG. 4(f), only the support body 50 and the adjustment layer 53 are removed. In this case, the surface plating layer 25 has already been formed. Thus, there is no need to form the surface plating layer 25 on the pad body 24 after the process of FIG. 4(f) like in the above embodiment. This reduces manufacturing processes. The surface plating layer 25 formed on the adjustment layer 53 may be, for example, a triple-layer surface plating layer including a gold layer 25b (0.005 to 0.5 μm), a palladium layer 25c (0.005 to 0.5 μm), and a nickel layer 25a (0.5 to 10 μm) as shown in FIG. 6(a). The surface plating layer 25 may also be a double-layer surface plating layer including a gold layer 25b (0.005 to 0.5 μm) and a nickel layer 25a (0.5 to 10 μm) as shown in FIG. 6(b). Alternatively, the surface plating layer 25 may be a double-layer surface plating layer including a gold layer 25b (0.005 to 0.5 μm) and a palladium layer 25c (0.005 to 0.5 μm) as shown in FIG. 6(c).

In the above embodiment, the electrode pad 23 includes the flat portion 26 and the projected portion 27. Further, as shown in FIG. 2, the inclined surface 27a of the projected portion 27 is flat. However, the shape of the projected portion 27 is not limited. For example, the surface of the projected portion 27 may be round instead of flat. In this case, it is preferred that a corner be formed in an interface between the surface of the projected portion and the flat surface of the flat portion. This obtains advantage (4) of the above embodiment.

In the wiring substrate 10 of the above embodiment, the electrode pad 23 is coupled by the solder ball 28 to a semiconductor element electrode pad. However, the electrode pad 23 may be coupled by a metal wire to a semiconductor element.

In the wiring substrate 10 of the above embodiment, the electrode pad 23 is coupled by the solder ball 28 to a semiconductor element, and a printed substrate is coupled to the third insulation layer 40 of the wiring substrate 10. However, the printed substrate may be coupled to the electrode pad 23, and a semiconductor element may be coupled to the third wires 41, that is, the portions of the solder resist 42 exposed from the openings 43.

In the manufacturing method of the above embodiment, subsequent to formation of the pad body 24, the first insulation layer 20 is formed after removing the resist 51. However, the first insulation layer 20 may be formed without removing the resist 51. In this case, the electrode pad 23 is formed on the manufactured wiring substrate in the corresponding opening 52 arranged in the surface of the resist 51.

In the above embodiment, epoxy resin is used as the material of the insulation layer, and copper is used as the material of the pad body in each electrode pad and the material of wires. However, other materials such as polyimide resin may be used for the insulation layer, and the material used for the pad body and wires is not limited to copper and may be changed. Further, the size of the recesses formed in the insulation layer, the size of the electrode pads, the thickness of each layer, and the wire pattern are not limited. The number of laminated insulation layers is also not limited. Further, the material for the support body and the adjustment layer used during manufacturing is not limited to copper and may be changed. Moreover, the adjustment layer only needs to be formed to include a flat surface and an inclined surface. The resist and plating liquid used to form the adjustment layer are not limited, and the process for forming the adjustment layer is not limited. For example, after forming an entirely flat adjustment layer, the peripheral part of the adjustment layer may be etched to form the inclined surface. Further, a process other than electrolytic plating may be performed to form the adjustment layer. In such a case, the process is not limited to the foregoing description.

All examples and conditional language recited herein are intended for pedagogical purposes to aid the reader in understanding the principles of the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

1. A method for manufacturing a wiring substrate including an electrode pad, the method comprising:
forming a resist on a support body, wherein the resist includes an opening at a location corresponding to where the electrode pad of the wiring substrate is formed;
forming an adjustment layer on the support body in the opening of the resist, wherein the adjustment layer includes a first flat surface, which is substantially parallel to the support body, and a first inclined surface, which extends from a rim of the first flat surface toward a side wall of the opening;
forming the electrode pad on the adjustment layer, wherein the electrode pad includes a peripheral part, which includes a second inclined surface corresponding to the first inclined surface of the adjustment layer, and a central part, which includes a second flat surface corresponding to the first flat surface of the adjustment layer, and the central part is recessed from the peripheral part;
forming an insulation layer on the support body;
forming a wiring layer on the insulation layer, wherein the wiring layer is electrically coupled to the electrode pad; and
removing the support body and the adjustment layer.

2. The method according to claim 1, further comprising forming a surface plating layer on the electrode pad after said removing the support body and the adjustment layer.

3. The method according to claim 1, wherein said forming the electrode pad includes forming a surface plating layer on the adjustment layer and forming an electrode pad body on the surface plating layer.

4. The method according to claim 1, further comprising performing a roughening process on the electrode pad after said forming the electrode pad.

5. The method according to claim 1, wherein the adjustment layer is formed by a plating.

6. The method according to claim 1, wherein the peripheral part includes a substantially flat distal end.

7. A wiring substrate comprising:
an insulation layer;
an electrode pad exposed from the insulation layer, wherein the electrode pad includes a central part, which includes a flat surface, and a peripheral part, and the central part is recessed from the peripheral part; and
a wiring layer arranged on the insulation layer and electrically coupled to the electrode pad.

8. The wiring substrate according to claim 7, wherein the electrode pad includes a pad body and a surface plating layer formed on the pad body.

9. The wiring substrate according to claim 7, wherein the peripheral part includes a substantially flat distal end.

10. A wiring substrate comprising:
an insulation layer including a recess, wherein the recess includes a bottom surface having an opening;
an electrode pad formed on the bottom surface of the recess in the insulation layer to cover the opening, wherein the electrode pad includes a central part, which includes a flat surface substantially parallel to the insulation layer, and a peripheral part, which includes an inclined surface extending from a rim of the central part toward a side wall of the opening, and the central part is recessed from the peripheral part; and
a wiring layer formed on the insulation layer, wherein the wiring layer is electrically coupled to the electrode pad through the opening in the bottom surface.
